(19) United States
(12) Patent Application Publication
(10) Pub. No.: US 2013/0340671 A1
(43) Pub. Date: Dec. 26, 2013

(54) SILICA GLASS CRUCIBLE, METHOD FOR MANUFACTURING SAME, AND METHOD FOR MANUFACTURING SILICON SINGLE CRYSTAL

(71) Applicants: Akihiro Kimura, Nishishirakawa (JP); Ryoji Hoshi, Nishishirakawa (JP); Nobuaki Mitamura, Nishishirakawa (JP); Hiroyuki Kamada, Nishishirakawa (JP)

(72) Inventors: Akihiro Kimura, Nishishirakawa (JP); Ryoji Hoshi, Nishishirakawa (JP); Nobuaki Mitamura, Nishishirakawa (JP); Hiroyuki Kamada, Nishishirakawa (JP)

(73) Assignee: SHIN-ETSU HANDOTAI CO., LTD., Tokyo (JP)

(21) Appl. No.: 14/003,348

(22) PCT Filed: Feb. 15, 2012
(86) PCT No.: PCT/JP2012/000975

§ 371 Date: Sep. 5, 2013

(30) Foreign Application Priority Data
Apr. 11, 2011 (JP) 2011-087083

(51) Int. Cl. C30B 15/10; C03B 20/00

(52) U.S. Cl. CPC C30B 15/10; C03B 20/00
USPC 117/13; 65/17.4; 117/208

(57) ABSTRACT

A method for manufacturing a silica glass crucible, includes: preparing a crucible base material that is made of silica glass and has a crucible shape; fabricating a synthetic silica glass material based on a direct method or a soot method; processing the synthetic silica glass material into the crucible shape without being pulverized; and bonding an inner wall of the crucible base material and an outer wall of the synthetic silica glass material processed into the crucible shape through a silica powder by performing a heat treatment. As a result, it is possible to provide the silica glass crucible that can avoid occurrence of dislocations of silicon single crystal at the time of manufacturing the silicon single crystal, has high heat-resisting properties, and can suppress a reduction in productivity and yield ratio, the manufacturing method thereof, and the method for manufacturing silicon single crystal using such a silica glass crucible.

### BACKGROUND OF THE INVENTION

1. Field of the Invention

The present invention relates to a silica glass crucible used for pulling silicon single crystal based on a Czochralski method, a method for manufacturing same, and a method for manufacturing silicon single crystal using such a silica glass crucible.

2. Description of the Related Art

For manufacture of silicon single crystal, a method called Czochralski method is extensively adopted. In manufacture of silicon single crystal based on this Czochralski method, generally, a silica glass crucible (which is also referred to as a quartz crucible) is filled with polycrystal silicon (polysilicon), the polysilicon is molten by heating to obtain a silicon melt, seed crystal is immersed in this silicon melt and then pulled up, and a silicon single crystal ingot is grown.

It has been conventionally said that air bubbles contained in the silica glass crucible expand at a high temperature during growth of silicon single crystal, a crucible inner surface is delaminated, and dislocations of the silicon single crystal occur (see, e.g., Patent Document 1) or that a silica glass crucible surface changes from amorphous into cristobalite and dislocations of the silicon single crystal occur due to delamination of the cristobalite (see, e.g., Patent Document 2).

In regard to cristobalite formation (crystallization) of the silica glass crucible surface during manufacture of the silicon single crystal based on the Czochralski method, according to Patent Document 3 and Patent Document 4, there are descriptions “crystallization occurs in the form of dots based on crystal generation nuclei on the initial stage of crystallization, and crystallization spreads in the form of a ring with progress of pulling of single crystal”, “crystallization spots are generated by such a crystallization progress phenomenon. Since outer peripheral portion of each crystallization spot is brown, it may be referred to as a brown spot in some cases”, and “although the crystallization spots increase with elapse of a single-crystal pulling time, i.e., a time that a silicon melt is directly contact with an inner surface of the quartz crucible, the crystallization spots converge on fixed density and maintain when a predetermined time passes”. Further, there is also a description “after such crystallization spots are produced, they start to be dissolved by the silicon melt, and a size of the crystallization spots is gradually reduced”.

It is said that this cristobalite formation of the silica glass crucible surface is promoted when concentration of impurities such as an alkali metal in the crucible is high. Further, considering an influence on device characteristic, lower impurity concentration is better. Therefore, absence of air bubbles or low impurity concentration is demanded for the silica glass crucible.

As a method for manufacturing synthetic silica glass containing no air bubbles and having very low impurity concentration, there is a direct method or a soot method. The direct method is a method for hydrolyzing a silicon compound such as silicon tetrachloride (SiCl₄) in oxyhydrogen flame and directly depositing/vitrifying this compound for synthesis. Further, the soot method is a method for manufacturing synthetic silica glass by the following procedure. First, a silicon compound such as silicon tetrachloride (SiCl₄) is hydrolyzed in oxyhydrogen flame at approximately 1100° C. which is a temperature lower than that in the direct method, and a lump (soot) of porous silica is thereby synthesized. This is subjected to a heat treatment in an appropriate gas such as a chlorine-based compound, and moisture is removed. At last, the soot is pulled down while being rotated at a temperature of approximately 1500° C. or more, and it is sequentially heated and vitrified from a lower end thereof (see Non-patent Document 1).

When such synthetic silica glass is used to manufacture a silica glass crucible, occurrence of dislocations of silicon single crystal can be avoided, but there is a problem that heat-resisting properties (which is also called thermal deformation resistance or deformation-resisting properties) of the crucible itself are low (i.e., the crucible is apt to deform at a high temperature). As a method for solving such a heat-resisting properties problem, for example, there is (1) a method for pulverizing synthetic silica glass synthesized from a silane compound, heating and melting it under vacuum, and molding it into a crucible (Patent Document 5) or (2) a method for forming a synthetic silica glass member having hydrogen molecule content of 1×10¹⁷ molecules/cm³ or more manufactured by a direct flame method for a silane compound into a synthetic silica glass powder through respective steps such as pulverization, particle size adjustment, and cleaning, then electrically melting it under vacuum at 1500 to 1900° C., and molding it (Patent Document 6).

According to the method of Patent Document 5, the synthetic silica glass is pulverized, a particle size at this moment is defined as 600 μm or less, this material is heated and molten under vacuum of 10⁻¹ Torr at 1500 to 1900° C., and hydroxyl group/chlorine content is lowered, thereby producing a synthetic silica glass crucible with good heat-resisting properties. Since heating and melting are performed under vacuum, air bubbles of 1 mm or more are not present in the crucible. This is better than an air bubble level of a silica glass crucible manufactured by a regular arc melting method (for example, approximately three air bubbles of 1 to 2 mm and no air bubbles of 2 mm or more per crucible). It is to be noted that the arc melting method is a method for supplying a raw material powder into a rotating mold, forming a raw material powder layer having a crucible shape, and performing arc discharge, heating, and melting from the inner side of the layer, thereby manufacturing a silica glass crucible (see, e.g., Patent Document 7).

Moreover, according to the method of Patent Document 6, the synthetic silica glass member having hydrogen molecule content of 1×10¹⁶ molecules/cm³ or more, a strain point of 1130° C. or more, and both OH group content and chlorine content of 1 ppm or less has high purity, and viscosity at high temperature can be 10¹⁰ poise or more at, e.g., 1400° C., and hence this member can be used as a silicon single crystal pulling crucible material.

Additionally, Patent Document 8 discloses a method for melting a quartz raw material powder in an inert gas atmosphere, holding it at 2000° C. or more and a degree of vacuum that is 0.05 Torr or more for five hours or more, refining it, attaching a resultant silica glass piece to an inner surface of a silica glass crucible, and heating and melting these members to be integrated. Further, as a heating and melting method for this process, using arc discharge, oxyhydrogen flame burner, and others are illustrated.

### PRIOR ART DOCUMENTS

### Patent Documents

Patent Document 1: Japanese Patent Laid-Open Publication No. H06-329493
Patent Document 2: Japanese Patent Laid-Open Publication No. 2001-342029
Patent Document 3: Japanese Patent Laid-Open Publication No. 2001-240494
Patent Document 4: Japanese Patent Laid-Open Publication No. H11-228291
Patent Document 5: Japanese Patent Laid-Open Publication No. H08-40735
Patent Document 6: Japanese Patent Laid-Open Publication No. H08-48532
Patent Document 7: Japanese Patent Laid-Open Publication No. 2005-239533
Patent Document 8: Japanese Patent Laid-Open Publication No. 2004-2082

### Non-Patent Document

Non-Patent Document 1: Practical Manual for Amorphous Siliceous Materials, Realize Inc., 1999

### SUMMARY OF THE INVENTION

As described above, to avoid occurrence of dislocations of silicon single crystal at the time of pulling the silicon single crystal based on the Czochralski method, a silica glass crucible having high purity (i.e., less impurities) and no air bubbles is demanded, and heat-resisting properties of the crucible are also required.

Since the synthetic quartz is pulverized in both the methods of Patent Document 5 and Patent Document 6, it can be said fewer air bubbles are contained in the crucible as compared with the arc melting method, but the number of air bubbles is not zero. Therefore, under present circumstances where a heat load on the silica glass crucible increases due to recent growth in size of silicon single crystal, air bubbles in the crucible expand during manufacture of the silicon single crystal. This results in a problem that dislocations of the silicon single crystal often occur.

Furthermore, a quartz material used in the method of Patent Document 8 is a silica glass piece obtained by melting the synthetic quartz powder and refining it. Therefore, quite a few air bubbles are contained in the silica glass piece. Therefore, even if the silicon single crystal is manufactured by using the silica glass crucible disclosed in Patent Document 8, there is a problem that occurrence of dislocations of the silicon single crystal cannot be sufficiently suppressed. Furthermore, in case of the heating and melting method, when the glass piece is welded to the silica glass crucible with use of the oxyhydrogen flame burner, heat cannot be transferred well, so this method is very difficult to be carried out in fact. Moreover, when the size of the crucible increases, the oxyhydrogen flame burner or the arc discharge has a high possibility of breakage of the crucible or the silica glass piece due to a large temperature gradient caused by local heating, and actually welding these members is very difficult.

As a method for solving such a problem, there has been devised a method for fabricating synthetic silica glass based on the direct method or the soot method, processing the synthetic silica glass into a crucible shape without being pulverized, and welding the synthetic silica glass processed into the crucible shape (which will be also referred to as an inner crucible hereinafter) to an inner surface of a crucible base material made of silica glass (which will be also referred to as an outer crucible hereinafter), thereby manufacturing a silica glass crucible.

Such a method enables fabricating the inner crucible which does not substantially contain air bubbles and has very low impurity concentration. Additionally, since this inner crucible is welded to the inner surface of the outer crucible, the silica glass crucible that can avoid occurrence of dislocations of silicon single crystal due to air bubbles or cristobalite formation and has good heat-resisting properties can be manufactured.

However, according to such a method, creating the inner crucible having an outer surface shape that perfectly fits to the inner surface shape of the outer crucible is not easy, and a gap may be formed between the outer wall of the inner crucible and the inner wall of the outer crucible in some cases. When this gap spreads due to heating at the time of manufacturing single crystal and the crucible expands, there is concern that the crucible may interfere with in-furnace components set above the crucible due to upward movement of the crucible through an operation and it may be damaged. Therefore, if such expansion of the crucible is confirmed, the operation must be quitted in the middle, the crystal that is being pulled cannot be pulled for a predetermined length, the multiple number of times (which means the number of times of refilling the crucible with a polycrystal silicon raw material) is reduced in case of pulling a plurality of single crystal rods, thereby reducing productivity and a yield ratio.

the present invention was made in view of the problem as described above, and is intended to provide a silica glass crucible that can avoid occurrence of dislocations of silicon single crystal at the time of manufacturing the silicon single crystal, has high heat-resisting properties, and can suppress a reduction in productivity and a yield ratio, a method for manufacturing same, and a method for manufacturing silicon single crystal using such a silica glass crucible.

To achieve this object, the present invention provides a method for manufacturing a silica glass crucible, comprising: a step of preparing a crucible base material that is made of silica glass and has a crucible shape; a step of fabricating a synthetic silica glass material based on a direct method or a soot method; a step of processing the synthetic silica glass material into the crucible shape without being pulverized; and a step of bonding an inner wall of the crucible base material and an outer wall of the synthetic silica glass material processed into the crucible shape through a silica powder by performing a heat treatment.

According to such a method, since the synthetic silica glass material fabricated by the direct method or the soot method is processed into the crucible shape without being pulverized, the crucible-shaped synthetic silica glass material which does not substantially contain air bubbles and has very low impurity concentration can be obtained. Further, since this synthetic silica glass material is bonded to the inner side of the crucible base material made of the silica glass, the portion made of the synthetic silica glass material in this silica glass crucible can be configured as the crucible inner surface that is in contact with the silicon melt at the time of manufacturing silicon single crystal, and occurrence of dislocations of the silicon single crystal due to air bubbles or cristobalite can be avoided.

Furthermore, since the crucible base material is bonded to the synthetic silica glass material through the silica powder, the gap between the inner wall of the crucible base material and the outer wall of the synthetic silica glass material is filled with the silica powder. As a result, it is possible to suppress spread of the gap due to heating at the time of pulling the silicon single crystal and expansion of the crucible, the operation does not have to be stopped due to damage of an in-furnace device or the crucible, and hence the silica glass crucible that can suppress a reduction in productivity and yield ratio can be manufactured.

Moreover, in this case, at the bonding step, the crucible base material and the synthetic silica glass material processed into the crucible shape are overlapped each other, then a hole communicating with a gap between the crucible base material and the synthetic silica glass material processed into the crucible shape from the outside of the crucible is provided by partly welding an upper portion of an inner wall of the crucible base material and an upper portion of an outer wall of the synthetic silica glass material processed into the crucible shape, the silica powder is introduced from the hole communicating with the gap for filling, and thereafter a heat treatment can be carried out.

As described above, when the upper portion of the inner wall of the crucible base material and the upper portion of the outer wall of the synthetic silica glass material are welded and then the gap between these members is filled with the silica powder, the synthetic silica glass material can be fixed to the crucible base material to some extent, and hence the silica powder can be stably added for filling. Additionally, as the method for filling the gap with the silica powder in this manner, the hole communicating with this gap is provided, and the silica powder is introduced through the hole communicating with this gap, thereby more efficiently and assuredly filling the gap with the silica powder.

Further, according to the method for manufacturing a silica glass crucible of the present invention, the bonding based on the heat treatment can be carried out simultaneously with and by heating at the time of arranging the synthetic silica glass material processed into the crucible shape in the crucible base material through the silica powder, filling the inside of the synthetic silica glass material with polysilicon, and melting the polysilicon in a silicon single crystal pulling device.

Furthermore, the present invention provides the method for manufacturing silicon single crystal, wherein the silica glass crucible is manufactured simultaneously with melting of the polysilicon, and subsequently the silicon single crystal is manufactured by pulling the silicon single crystal from the silicon melt produced by the melting of the polysilicon based on the Czochralski method.

As described above, when the synthetic silica glass material is bonded to the crucible base material by heating at the time of melting the polysilicon in the silicon single crystal pulling device and then the silicon single crystal is pulled from the silicon melt, the number of steps can be reduced as a whole, and the crucible does not have to be temporarily cooled. Therefore, total energy and a manufacturing time required for manufacturing the silicon single crystal can be decreased.

Moreover, according to the method for manufacturing a silica glass crucible of the present invention, the bonding can be carried out by arranging the synthetic silica glass material processed into the crucible shape in the crucible base material through the silica powder and heating the crucible base material and the synthetic silica glass material with use of an electric furnace.

Additionally, according to the method for manufacturing a silica glass crucible of the present invention, the bonding can be carried out by arranging the synthetic silica glass material processed into the crucible shape in the crucible base material through the silica powder and heating the crucible base material and the synthetic silica glass in a silicon single crystal pulling device.

As describe above, the synthetic silica glass material can be bonded to the crucible base material by the electric furnace or by heating in the pulling device. Further, since the entire members can be bonded at a time, a local temperature gradient does not occur, and cracking does not occur either.

Furthermore, according to the method for manufacturing a silica glass crucible of the present invention, at the step of fabricating the synthetic silica glass material, it is preferable to fabricate the synthetic silica glass material as a tabular material having a thickness of 1 mm or more.

When the synthetic silica glass material is fabricated in this manner, damage at the time of processing into the crucible shape can be avoided. Moreover, after processing the material into the crucible shape and arranging it in the crucible base material through the silica powder or after bonding, damage at the time of adding polysilicon which is a raw material of the silicon single crystal can be avoided.

Additionally, according to the method for manufacturing a silica glass crucible of the present invention, at the step of processing the synthetic silica glass material into the crucible shape, the crucible shape can be formed from one or more synthetic silica glass materials.

As described above, in regard to the processing of the synthetic silica glass material into the crucible shape, one synthetic silica glass material may be formed into the crucible shape, or a plurality of synthetic silica glass materials may be combined by welding or the like to be formed into the crucible shape.

Further, the present invention provides a silica glass crucible manufactured by any method for manufacturing a silica glass crucible described above.

That is, the present invention provides a silica glass crucible comprising: a crucible base material that is made of silica glass and has a crucible shape; and a synthetic silica glass material processed into the crucible shape without being pulverized,

wherein the synthetic silica glass material is fabricated by a direct method or a soot method and does not substantially contain air bubbles, and an inner wall of the crucible base material is bonded to an outer wall of the synthetic silica glass material through a silica powder.

Since such a silica glass crucible is the silica glass crucible obtained by bonding the synthetic silica glass material manufactured by the direct method or the soot method, i.e., the synthetic silica glass material which does not substantially contain air bubbles and has extremely low impurity concentration to the inner side of the crucible base material, it is possible to avoid dislocations of the silicon single crystal caused due to air bubbles or cristobalite at the time of manufacturing the silicon single crystal. Furthermore, heat-resisting properties of the silica glass crucible can be assured.

Moreover, since the crucible base material and the synthetic silica glass material are bonded through the silica powder, the gap between the inner wall of the crucible base material and the outer wall of the synthetic silica glass material is filled with the silica powder. As a result, the crucible does not expand due to heating during manufacture of the single crystal and the operation does not have to be stopped, thus obtaining the crucible that can suppress a reduction in productivity and a yield ratio.

Additionally, it is preferable for the synthetic silica glass material to have a thickness of 1 mm or more.

When such a material is used, contact between the silicon melt and the silica powder or the crucible base material due to melting of the synthetic silica glass material can be avoided during manufacture of the silicon single crystal. As a result, the silicon melt can be constantly in contact with the crucible inner surface which does not substantially contain air bubbles and has very low impurity concentration, and occurrence of dislocations of the silicon single crystal can be more effectively avoided.

Further, the present invention provides the method for manufacturing silicon single crystal, wherein a silicon melt is held in any silica glass crucible described above, and silicon single crystal is manufactured by pulling the silicon single crystal from the silicon melt by a Czochralski method.

As described above, according to the method for manufacturing silicon single crystal based on the Czochralski method using the silica glass crucible of the present invention, the silicon single crystal can be manufactured with avoiding occurrence of dislocations of the silicon single crystal due to air bubbles or cristobalite, and suppressing a reduction in productivity and a yield ratio due to stoppage of the operation caused by expansion of the crucible.

As described above, according to the method for manufacturing silica glass crucible of the present invention, a silica glass crucible that the synthetic silica glass material that does not substantially contain air bubbles and has very low impurity concentration because it is fabricated by the direct method or the soot method and it is not pulverized is configured as the crucible inner surface that is in contact with the silicon melt at the time of manufacturing the silicon single crystal can be manufactured. Furthermore, filling the gap between the crucible base material and the synthetic silica glass material with the silica powder enables suppressing expansion of the crucible due to heating during manufacture of the single crystal. Moreover, when such a silica glass crucible is used for manufacture of the silicon single crystal, dislocations of the silicon single crystal caused due to air bubbles or cristobalite can be prevented from occurring, stoppage of the operation owing to damage to the in-furnace device or the crucible can be avoided, and a reduction in productivity and yield ratio can be suppressed.

### BRIEF DESCRIPTION OF DRAWING

FIG. 1

This is a drawing showing an example of a schematic cross-sectional view and a top view of a silica glass crucible according to the present invention.

### DETAILED DESCRIPTION OF THE PREFERRED EMBODIMENTS

Although the present invention will be explained hereinafter in detail, the present invention is not restricted thereto.

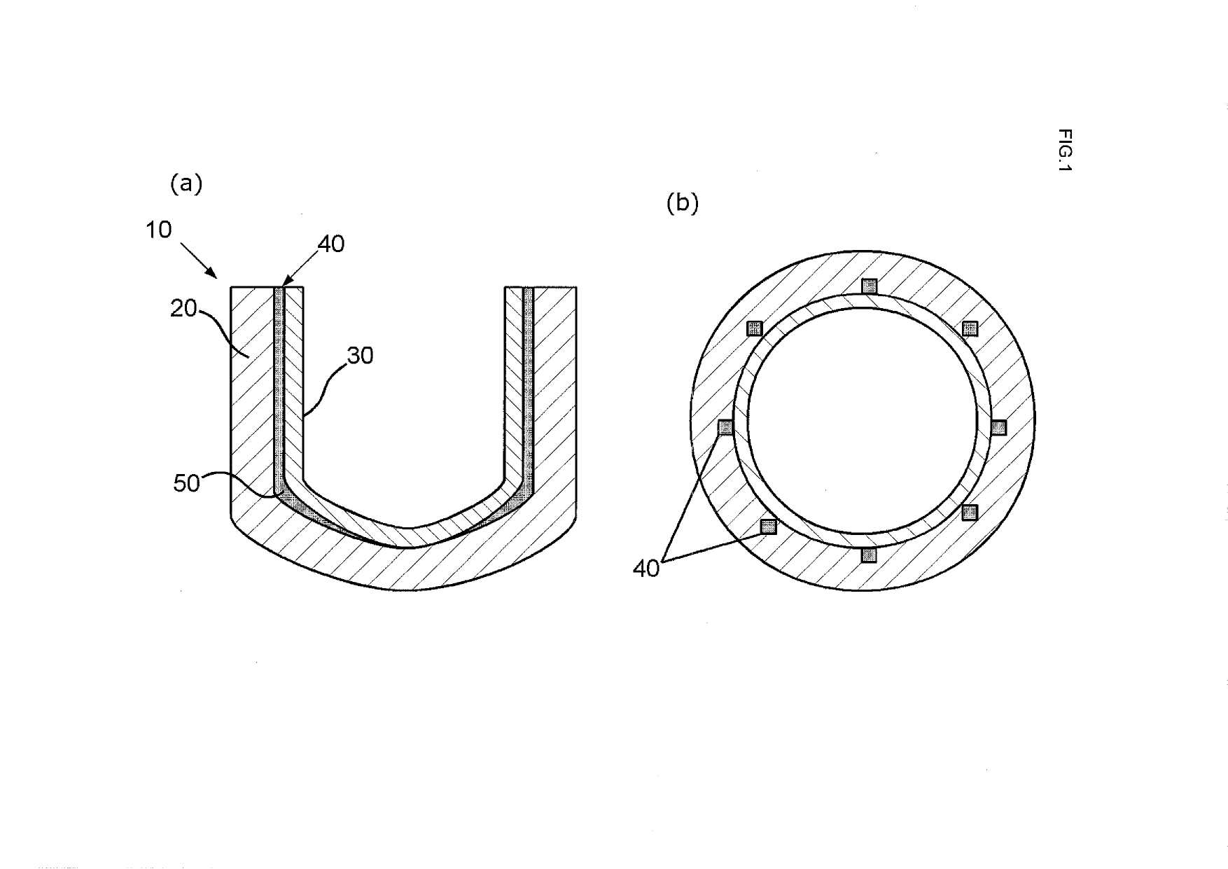

As an example of a silica glass crucible according to the present invention, such a silica glass crucible as shown in FIG. 1 will be explained.

A silica glass crucible 10 according to the present invention is made of silica glass and includes a crucible base material 20 having a crucible shape and a synthetic silica glass material 30 having a crucible shape placed on the inner side of the crucible base material 20. This synthetic silica glass material 30 is fabricated by the direct method or the soot method, and it does not substantially contain air bubbles.

As will be described later, the synthetic silica glass material 30 is obtained by processing and forming the synthetic silica glass material fabricated by the direct method or the soot method into the crucible shape without being pulverized.

Even if the thermally deformable synthetic silica glass material 30 is used as a material constituting the silica glass crucible 10, since this material is placed inside the crucible base material 20, heat-resisting properties can be imposed on the crucible base material 20, and thus the heat-resisting properties of the silica glass crucible 10 can be assured.

Further, a gap between the crucible base material 20 and the synthetic silica glass material 30 is filled with a silica powder 50. The crucible base material 20 is bonded to the synthetic silica glass material 30 through the silica powder 50 sintered or solidified after being dissolved.

Since such a silica powder 50 is added, the gap between the crucible base material 20 and the synthetic silica glass material 30 can be prevented from spreading due to heating during manufacture of single crystal, and expansion of the silica glass crucible 10 can be suppressed.

Here, since purity and a particle size of the silica powder 50 are not restricted in particular and the silica powder 50 does not directly come into contact with a silicon melt, a natural powder with low purity can be used, but a synthetic powder containing less impurity is preferable because a reduction in impurity contamination can be expected.

Such a silica glass crucible 10 can be manufactured as follows.

First, the crucible base material 20 that is made of the silica glass and has the crucible shape is prepared (step a).

The crucible base material 20 prepared here may be a regular silica glass crucible. However, to discriminate it from the silica glass crucible 10 manufactured according to the present invention, this crucible base material is called “crucible base material” in the description of the present invention. As the crucible base material 20 according to the present invention, a silica glass crucible that is industrially used nowadays can be adopted, a manufacturing method thereof is not restricted and, for example, an arc melting method that is currently industrially carried out can be used. The arc melting method is such a method as disclosed in Patent Document 7 for supplying a raw material powder into such a rotating mold, forming a raw material powder layer having a crucible shape, and performing arc discharge heating and melting from the inner side of this layer to manufacture a silica glass crucible. Besides, a sol-gel method or a slip cast method can be used for manufacturing the crucible base material. In this case, an inner surface of the crucible base material does not have to form a high-purity layer or an air bubble-less layer.

On the other hand, the crucible-shaped synthetic silica glass material 30 that is to be bonded to the inner side of the crucible base material 20 through the silica powder 50 is prepared as follows.

First, the synthetic silica glass material is fabricated by the direct method or the soot method (step b). According to the direct method or the soot method, the synthetic silica glass material that does not substantially contain air bubbles and has very low impurity concentration can be fabricated.

At this time, fabricating the synthetic silica glass material as a plate-shaped material having a thickness of 1 mm or more is preferable. If the synthetic silica glass material has the thickness of 1 mm or more, damage at the time of processing into the crucible shape can be avoided as will be described later. Furthermore, damage at the time of adding polysilicon that is a raw material of the silicon single crystal can be also avoided as will be described later. On the other hand, as the thickness of the synthetic silica glass material, 10 mm or less is desirable. If it has such a thickness, the processing time such as R processing is not extremely increased. Moreover, the plate-shaped synthetic silica glass material is also commercially available for a photomask and others, and it can be easily obtained.

Then, the synthetic silica glass material is processed into the crucible shape without being pulverized (step c). As a result, the synthetic silica glass material 30 having such a crucible shape as shown in FIG. 1 can be obtained.

At this step, since the synthetic silica glass material fabricated by the direct method or the soot method is processed without being pulverized, the crucible-shaped synthetic silica glass material 30 that does not substantially contain air bubbles and has very low impurity concentration can be obtained. Additionally, the number of steps can be reduced, and hence the material can be prepared at low cost.

It is to be noted that “pulverization of the synthetic silica glass material” that is not performed in manufacture of the silica glass crucible according to the present invention means processing from the synthetic silica glass material into a powder (e.g., a powder having an average particle diameter of 1 mm or less), namely, directly cutting and processing the synthetic silica glass material manufactured by the direct method or the soot method into, e.g., a lump shape or a plate shape is not included. In manufacture of the silica glass crucible according to the present invention, such cutting or processing can be carried out.

At this step c, processing the synthetic silica glass material into the crucible shape can suffice, and its specific method is not restricted in particular. At the time of fabricating the crucible-shaped synthetic silica glass material 30, a distortion removing heat treatment or acid cleaning for removing impurities introduced during the processing steps can be appropriately carried out. Furthermore, in processing of the synthetic silica glass material into the crucible shape, the crucible shape may be formed from one synthetic silica glass material, or the crucible shape may be formed from a plurality of synthetic silica glass materials.

To form the crucible shape from one synthetic silica glass material, for example, the synthetic silica glass material can be pressed against a carbon or synthetic quartz jig with heating, or the synthetic silica glass material can be processed into the crucible shape at once by its own weight. In such a case, when the synthetic silica glass material is formed into a plate-like shape in advance, the processing can be facilitated, which is preferable.

In case of forming the crucible shape from the plurality of synthetic silica glass materials, the respective synthetic silica glass materials can be formed into synthetic silica glass pieces that can be readily formed into crucible shapes. The individual shapes of such synthetic silica glass pieces are not restricted in particular.

In regard to the plurality of synthetic silica glass materials, the crucible shape can be formed from the plurality of synthetic silica glass materials by R processing or welding using an oxyhydrogen flame burner or the like. Such processing, welding, or the like may be performed before a later-described step of bonding to the crucible base material (step d).

The synthetic silica glass material 30 having the crucible shape is prepared through the above-described step b and step c.

It is to be noted that the preparation of the crucible base material (step a), and the fabrication of the synthetic silica glass material and the processing into the crucible shape (step b and step c) can be independently performed, either of the steps can be performed first, or these steps can be performed in parallel.

Then, the synthetic silica glass material 30 processed into the crucible shape is bonded to the inner side of the crucible base material 20 through the silica powder 50 (step d), whereby the silica glass crucible 10 is manufactured. Here, a gap between the crucible base material 20 and the synthetic silica glass material 30 must be filled with the silica powder 50, a filling method is not restricted in particular.

For example, as shown in FIG. 1, the crucible base material 20 and the synthetic silica glass 30 are overlapped each other, then holes 40 communicating with the gap between the crucible base material 20 and the synthetic silica glass material 30 are provided from the outside (an upper portion) of the silica glass crucible 10 by partly welding an upper portion of an inner wall of the crucible base material 20 and an upper portion of an outer wall of the synthetic silica glass material 30 (i.e., leaving a portion that is not welded), the silica powder 50 can be introduced and added from the holes 40. According to such a method, the crucible base material 20 and the synthetic silica glass material 30 are fixed to some extent, and then the silica powder 50 can be introduced, which is preferable.

Moreover, when the holes 40 are provided at a plurality of positions, the silica powder 50 can be more efficiently introduced, which is preferable.

This bonding must be assuredly carried out. Specifically, there are the following three methods.

### (First Bonding Method)

According to the first bonding method, the synthetic silica glass material 30 processed into the crucible shape is first arranged (set) in the crucible base material 20. As the synthetic silica glass material 30 having the crucible shape, either one processed into the crucible shape from one synthetic silica glass material or one formed into the crucible shape by welding a plurality of synthetic silica glass materials can be used. Additionally, the gap between the crucible base material 20 and the synthetic silica glass material 30 is filled with the silica powder 50 in advance, and this material is arranged in the silicon single crystal pulling device. Subsequently, the inside of the synthetic silica glass material 30 is filled with polysilicon. At this time, the inside of the synthetic silica glass material 30 may be filled with the polysilicon in advance, and then the crucible filled with the polysilicon may be arranged in the silicon single crystal pulling device. Subsequently, the polysilicon is heated in the silicon single crystal pulling device, and the bonding of the crucible base material 20 and the crucible-shaped synthetic silica glass material 30 through the silica powder 50 is performed simultaneously with the melting of the polysilicon by heating at the time of melting this polysilicon in the silicon single crystal pulling device. Power (electric power supplied for heating) and a heating time are arbitrary, and it can be determined in dependence on a size of the pulling device, the crucible, and others like the melting of the regular polysilicon.

According to this method, the silica glass crucible 10 is manufactured simultaneously with the melting of the polysilicon. In this case, after the melting of the polysilicon and the manufacture of the silica glass crucible, the silicon single crystal is pulled from the silicon melt produced by the melting of the polysilicon in the pulling device based on the Czochralski method, thereby manufacturing the silicon single crystal.

Thus, after the silica glass crucible 10 is manufactured, it does not have to be temporarily cooled until the silicon single crystal is manufactured. Therefore, total energy required for manufacturing the silicon single crystal can be decreased. Additionally, the number of manufacturing steps can be minimized, an increase in cost can be suppressed, and presence of the silicon melt provided inside enables uniformly bonding the synthetic silica glass material to the crucible base material.

### (Second Bonding Method)

According to the second bonding method, the synthetic silica glass material 30 processed into the crucible shape is arranged in the crucible base material 20, and the gap between the crucible base material 20 and the synthetic silica glass material 30 is filled with the silica powder 50 in advance. Then, an electric furnace is used, the crucible base material 20 and the synthetic silica glass material 30 are heated, and these members are bonded through the silica powder 50.

### (Third Bonding Method)

According to the third bonding method, the synthetic silica glass material 30 processed into the crucible shape is arranged in the crucible base material 20, and the gap between the crucible base material 20 and the synthetic silica glass material 30 is filled with the silica powder 50 in advance. Then, in the silicon single crystal pulling device, the crucible base material 20 and the synthetic silica glass material 30 are heated, and they are bonded through the silica powder 50.

In case of the second or third bonding method, as the synthetic silica glass material 30 having the crucible shape, one processed into the crucible shape from one synthetic silica glass material or one formed into the crucible shape by, e.g., performing R processing from a plurality of synthetic silica glass materials and then welding them can be arranged in the crucible base material 20.

Additionally, power (electric power supplied for heating) and a heating time is arbitrary, and it can be determined as required.

In addition, according to any one of the first to third bonding methods, it is preferable to provide air vents so that an atmospheric gas cannot be trapped in the gap between the crucible base material 20 and the synthetic silica glass material 30.

The silica glass crucible 10 shown in FIG. 1 can be manufactured through the above-described steps a to d.

When the silicon single crystal is manufactured by using such a silica glass crucible 10 according to the present invention based on the Czochralski method, the silicon single crystal can be manufactured with avoiding occurrence of dislocations of the silicon single crystal due to air bubbles or cristobalite.

The silicon single crystal can be manufactured based on the regular Czochralski method except for using the silica glass crucible 10 according to the present invention. That is, the silicon melt is held in the silica glass crucible 10 according to the present invention, and the silicon single crystal is pulled from the silicon melt by the Czochralski method, whereby the silicon single crystal is manufactured. Further, it is possible to appropriately carry out a well-known technique concerning the Czochralski method, e.g., growing the silicon single crystal with applying magnetic fields.

However, in case of the “first bonding method”, as described above, the bonding of the crucible base material 20 and the synthetic silica glass material 30 through the silica powder 50 is carried out simultaneously with the melting of the polysilicon by heating at the time of melting the polysilicon in the silicon single crystal pulling device. According to this method, the silicon single crystal can be subsequently pulled from the silicon melt like manufacture of the silicon single crystal based on the regular Czochralski method.

It is to be noted that a thickness of the bonded synthetic silica glass material 30 constituting the silica glass crucible 10 is 1 mm or more is preferable. To achieve this thickness, for example, in the fabrication of the synthetic silica glass material (step b), the synthetic silica glass material is fabricated as a tabular material having the thickness of 1 mm or more, processed into the crucible shape, and bonded to the crucible base material 20 through the silica powder 50.

If the synthetic silica glass material 30 has the thickness of 1 mm or more, damage at the time of adding the polysilicon as a raw material of the silicon single crystal can be avoided. Furthermore, during manufacture of the silicon single crystal, contact of the silicon melt and the silica powder 50 or the crucible base material 20 due to melting of the synthetic silica glass material 30 can be avoided. As a result, the silicon melt can be constantly brought into contact with the crucible inner surface that does not substantially contain air bubbles and has very low impurity concentration, thus more effectively avoiding occurrence of dislocations of the silicon single crystal. On the other hand, if the thickness of the synthetic silica glass material 30 is 10 mm or less, which is desirable in terms of cost.

### EXAMPLES

Although the present invention will be more specifically explained hereinafter based on an example and comparative examples, the present invention is not restricted by them.

### Example 1

As shown in FIG. 1, a silica glass crucible having a diameter of 26 inches (660 mm) was configured as an outer crucible, and a material obtained by deforming/processing a synthetic silica glass plate with a thickness of 5 mm fabricated by the direct method into a crucible shape with a diameter of 620 mm was configured as an inner crucible, and an upper portion of an inner wall of the outer crucible and an upper portion of an outer wall of the inner crucible were welded so that holes having a length of 20 mm can be formed at eight positions. Then, a gap between the outer crucible and the inner crucible was filled with 15 kg of a silica powder from the holes provided at eight positions, thereby filling the gap. The thus prepared inner crucible was filled with 170 kg of a polysilicon raw material, and the polysilicon raw material was molten in the silicon single crystal pulling device. At this time, the silica powder filling the gap was turned to a sintered body simultaneously with melting of the polysilicon raw material, thus bonding the crucibles.

10 such silica glass crucibles (=10 batches) were prepared, and two silicon single crystals having a diameter of 200 mm were pulled in each crucible. As a result, the gap between the inner crucible and the outer crucible does not expand in all the crucibles at the time of pulling each of the first and second silicon single crystal, and the inner crucible did not expand either. Further, dislocations did not occur in both the pulled silicon single crystals at all, and a total of 20 DF (dislocation-free) crystals were pulled without re-melting, an operation of pulling two silicon single crystals was able to be finished as originally planned. The following Table 1 shows a result of this operation.

### Comparative Example 1

A material obtained by deforming/processing a synthetic silica glass plate with a thickness of 5 mm fabricated by the direct method into a crucible shape was set on the inner side of a silica glass crucible having a diameter of 26 inches (660 mm), and upper ends of both members were welded with use of an oxyhydrogen flame burner. The obtained product was filled with a polysilicon raw material, and the polysilicon raw material was molten. That is, a gap between the inner crucible and the outer crucible was not filled with a silica powder. It is to be noted that a charge amount of the polysilicon is 170 kg.

10 such silica glass crucibles (=10 batches) were prepared, and two silicon single crystals having a diameter of 200 mm were pulled in each crucible. As a result, in case of pulling the first crystal in all the crucibles, the gap between the inner crucible and the outer crucible did not expand, and the inner crucible did not expand either. Furthermore, dislocations of the silicon crystal did not occur at all, and 10 DF (dislocation-free) crystals were obtained without re-melting. However, in case of pulling the second crystal, the inner crucible expanded inwardly in two crucibles, and pulling the crystal had to be given up. The following Table 1 shows a result of this operation.

### Comparative Example 2

A conventional silica glass crucible having a diameter of 26 inches (660 mm) was filled with a polysilicon raw material, and the polysilicon raw material was molten. It is to be noted that a charge amount of polysilicon is 170 kg.

10 such silica glass crucibles (=10 batches) were prepared, and two silicon single crystals having a diameter of 200 mm were pulled in each crucible. As a result, in the crucibles in total, dislocations of silicon crystal occurred nine times in case of the first crystal, and the same occurred five times in case of the second crystal. A total of 20 DF (dislocation-free) crystals were eventually obtained by re-melting the silicon crystal, but productivity was lowered due to the re-melting. The following Table 1 shows a result of this operation.

It is to be noted that, since the conventional silica glass crucible constituted of the outer crucible alone is used in Comparative Example 2, expansion of the crucible, which is caused due to expansion of the gap between the inner crucible and the outer crucible by heat, does not occur as a matter of course. Therefore, in the following Table 1, oblique lines are given in order to be distinguished from the result of Example 1.

TABLE 1

| | | | Comparative | | Comparative | |
|---|---|---|---|---|---|---|
| | Example | | Example 1 | | Example 2 | |
| Crucible form | Inner crucible + | | Inner crucible + | | Conventional | |
| | Outer crucible | | Outer crucible | | quartz crucible | |
| | Gap is filled | | Gap is not filled | | (Outer crucible | |
| | with silica | | with silica | | only) | |
| Multi number | 1 | 2 | 1 | 2 | 1 | 2 |
| Total number of | 0 | 0 | 0 | 0 | 9 | 5 |
| dislocation in 10 | | | | | | |
| batches | | | | | | |
| Number of | 0 | 0 | 0 | 2 | | |
| expanded crucibles | | | | | | |

As can be understood from Table 1, based on the method for manufacturing a silica glass crucible of the present invention, when the synthetic silica glass material containing no air bubbles and having very low impurity concentration is used as the material constituting the crucible inner surface portion, occurrence of dislocations of the silicon single crystal can be suppressed. Moreover, at this time, when the gap between the outer crucible and the inner crucible is filled with the silica powder and these crucibles are bonded through the silica powder, it is possible to suppress expansion of the crucible during manufacture because of expansion of the gap caused due to heating during manufacture of the single crystal.

It is to be noted that, when the dislocations have occurred in the comparative examples, re-melting is performed, the silicon single crystal is grown again, and the dislocation-free silicon single crystal is eventually obtained. However, to shorten a manufacturing time and improve productivity, avoiding occurrence of dislocations is demanded, and the present invention is very effective for the improvement in productivity. Moreover, since the high-purity synthetic silica glass is in contact with the silicon melt, the resultant silicon single crystal can have high purity.

It is to be noted that the present invention is not restricted to the foregoing embodiment. The foregoing embodiment is an illustrative example, and whatever having substantially the same configuration as the technical concept described in claims according to the present invention and exhibiting the same functions and effects is included in the technical scope of the present invention.

1-12. (canceled)

13. A method for manufacturing a silica glass crucible, comprising:
a step of preparing a crucible base material that is made of silica glass and has a crucible shape;
a step of fabricating a synthetic silica glass material based on a direct method or a soot method;
a step of processing the synthetic silica glass material into the crucible shape without being pulverized; and
a step of bonding an inner wall of the crucible base material and an outer wall of the synthetic silica glass material processed into the crucible shape through a silica powder by performing a heat treatment.

14. The method for manufacturing a silica glass crucible according to claim 13,
wherein, at the bonding step, the crucible base material and the synthetic silica glass material processed into the crucible shape are overlapped each other, then a hole communicating with a gap between the crucible base material and the synthetic silica glass material processed into the crucible shape from the outside of the crucible is provided by partly welding an upper portion of an inner wall of the crucible base material and an upper portion of an outer wall of the synthetic silica glass material processed into the crucible shape, the silica powder is introduced from the hole communicating with the gap for filling, and thereafter a heat treatment is carried out.

15. The method for manufacturing a silica glass crucible according to claim 13,
wherein the bonding based on the heat treatment is carried out simultaneously with and by heating at the time of arranging the synthetic silica glass material processed into the crucible shape in the crucible base material through the silica powder, filling the inside of the synthetic silica glass material with polysilicon, and melting the polysilicon in a silicon single crystal pulling device.

16. The method for manufacturing a silica glass crucible according to claim 14,
wherein the bonding based on the heat treatment is carried out simultaneously with and by heating at the time of arranging the synthetic silica glass material processed into the crucible shape in the crucible base material through the silica powder, filling the inside of the synthetic silica glass material with polysilicon, and melting the polysilicon in a silicon single crystal pulling device.

17. The method for manufacturing a silica glass crucible according to claim 13,
wherein the bonding based on the heat treatment is carried out by arranging the synthetic silica glass material processed into the crucible shape in the crucible base material through the silica powder and heating the crucible base material and the synthetic silica glass material with use of an electric furnace.

18. The method for manufacturing a silica glass crucible according to claim 14,
wherein the bonding based on the heat treatment is carried out by arranging the synthetic silica glass material processed into the crucible shape in the crucible base material through the silica powder and heating the crucible base material and the synthetic silica glass material with use of an electric furnace.

19. The method for manufacturing a silica glass crucible according to claim 13,
wherein the bonding based on the heat treatment is carried out by arranging the synthetic silica glass material processed into the crucible shape in the crucible base material through the silica powder and heating the crucible base material and the synthetic silica glass in a silicon single crystal pulling device.

20. The method for manufacturing a silica glass crucible according to claim 14,
wherein the bonding based on the heat treatment is carried out by arranging the synthetic silica glass material processed into the crucible shape in the crucible base material through the silica powder and heating the crucible base material and the synthetic silica glass in a silicon single crystal pulling device.

21. The method for manufacturing a silica glass crucible according to claim 13,
wherein, at the step of fabricating the synthetic silica glass material, the synthetic silica glass material is fabricated as a tabular material having a thickness of 1 mm or more.

22. The method for manufacturing a silica glass crucible according to claim 14,
wherein, at the step of fabricating the synthetic silica glass material, the synthetic silica glass material is fabricated as a tabular material having a thickness of 1 mm or more.

23. The method for manufacturing a silica glass crucible according to claim 15,
wherein, at the step of fabricating the synthetic silica glass material, the synthetic silica glass material is fabricated as a tabular material having a thickness of 1 mm or more.

24. The method for manufacturing a silica glass crucible according to claim 17,
wherein, at the step of fabricating the synthetic silica glass material, the synthetic silica glass material is fabricated as a tabular material having a thickness of 1 mm or more.

25. The method for manufacturing a silica glass crucible according to claim 19,
wherein, at the step of fabricating the synthetic silica glass material, the synthetic silica glass material is fabricated as a tabular material having a thickness of 1 mm or more.

26. The method for manufacturing a silica glass crucible according to claim 13,
wherein, at the step of processing the synthetic silica glass material into the crucible shape, the crucible shape is formed from one or more synthetic silica glass materials.

27. A silica glass crucible manufactured by the method for manufacturing a silica glass crucible according to claim 13.

28. A silica glass crucible comprising:
a crucible base material that is made of silica glass and has a crucible shape; and
a synthetic silica glass material processed into the crucible shape without being pulverized,
wherein the synthetic silica glass material is fabricated by a direct method or a soot method and does not substantially contain air bubbles, and an inner wall of the crucible base material is bonded to an outer wall of the synthetic silica glass material through a silica powder.

29. The silica glass crucible according to claim 28,
wherein the synthetic silica glass material has a thickness of 1 mm or more.

30. A method for manufacturing silicon single crystal,
wherein a silicon melt is held in the silica glass crucible according to claim 28, and silicon single crystal is manufactured by pulling the silicon single crystal from the silicon melt based on a Czochralski method.

31. A method for manufacturing silicon single crystal,
wherein the silica glass crucible is manufactured by the method for manufacturing a silica glass crucible according to claim 15 simultaneously with melting of the polysilicon, and subsequently silicon single crystal is manufactured by pulling the silicon single crystal from the silicon melt produced by the melting of the polysilicon based on the Czochralski method.

32. A method for manufacturing silicon single crystal,
wherein the silica glass crucible is manufactured by the method for manufacturing a silica glass crucible according to claim 16 simultaneously with melting of the polysilicon, and subsequently silicon single crystal is manufactured by pulling the silicon single crystal from the silicon melt produced by the melting of the polysilicon based on the Czochralski method.
